(19) United States
(12) Patent Application Publication
(10) Pub. No.: US 2024/0429042 A1
(43) Pub. Date: Dec. 26, 2024

(54) SEMICONDUCTOR STRUCTURE AND METHOD FOR MANUFACTURING SAME

(71) Applicant: CXMT CORPORATION, Hefei (CN)

(72) Inventors: Yihang WANG, Hefei (CN); Dingdong KUANG, Hefei (CN); Dong YAN, Hefei (CN); Jun WEI, Hefei (CN); Jia KANG, Hefei (CN); Wei LI, Hefei (CN)

(21) Appl. No.: 18/822,469

(22) Filed: Sep. 3, 2024

Related U.S. Application Data
(63) Continuation of application No. PCT/CN2023/126732, filed on Oct. 26, 2023.

(30) Foreign Application Priority Data
Feb. 13, 2023 (CN) 202310104747.0

(51) Int. Cl. H01L 21/02; C23C 16/40; C23C 16/505

(52) U.S. Cl. CPC H01L 21/02216; C23C 16/401; C23C 16/505; H01L 21/02126; H01L 21/02274

(57) ABSTRACT

Provided are a semiconductor structure and a method for manufacturing same. The semiconductor structure includes a target structure, a low dielectric constant material layer disposed on the target structure, and a protective layer disposed on the low dielectric constant material layer. The low dielectric constant material layer and the protective layer are prepared from the same precursor, and the protective layer has a lower carbon content.

### CROSS-REFERENCE TO RELATED APPLICATIONS

This application is a continuation application of International Patent Application No. PCT/CN2023/126732, filed on Oct. 26, 2023, which is based on and claims priority to the Chinese Patent Application No. 202310104747.0, filed on Feb. 13, 2023, and entitled “SEMICONDUCTOR STRUCTURE AND METHOD FOR MANUFACTURING SAME”, and claims priority to the Chinese Patent Application, which is incorporated herein by reference in its entirety.

### TECHNICAL FIELD

The present disclosure relates to but is not limited to a semiconductor structure and a method for manufacturing same.

### BACKGROUND

As a continuous decrease in the size of a semiconductor device, the distance between metal lines is closer, causing an increase in parasitic capacitance between the metal lines, which becomes an important factor affecting the operating speed of the semiconductor device. To reduce the parasitic capacitance between the metal lines, a low dielectric constant material is adopted instead of silicon oxide as an interlayer dielectric between the metal lines, to alleviate the response delay of the semiconductor device.

However, after the low dielectric constant material is etched, a “sharp corner” profile is prone to appear on the surface, which is inconducive to process integration. Therefore, the low dielectric constant material is adopted as the interlayer dielectric between the metal lines, and it is necessary to grow an oxide layer on the surface of the low dielectric constant material, to protect the low dielectric constant material from having the “sharp corner” profile after being etched, facilitating process integration and improvement of process stability.

### SUMMARY

The following is an overview of a subject matter described in detail in the present disclosure. This overview is not intended to limit the protection scope of the claims.

The present disclosure provides a semiconductor structure and a method for manufacturing same.

A first aspect of the present disclosure provides a semiconductor structure, including a target structure, and further including the following:
a low dielectric constant material layer, disposed on the target structure; and
a protective layer, disposed on the low dielectric constant material layer.

The low dielectric constant material layer and the protective layer are prepared from the same precursor, and the protective layer has a lower carbon content.

According to some embodiments of the present disclosure, at least one type of cyclic organosiloxane is included in the precursor.

According to some embodiments of the present disclosure, octamethylcyclotetrasiloxane is included in the at least one type of cyclic organosiloxane.

According to some embodiments of the present disclosure, a dielectric constant of the low dielectric constant material layer is less than 3.

According to some embodiments of the present disclosure, a silicon oxide-carbon material is included in a material of the low dielectric constant material layer, and a carbon-doped silicon oxide material is included in a material of the protective layer.

According to some embodiments of the present disclosure, a carbon content of the protective layer is less than 5%.

According to some embodiments of the present disclosure, a carbon content of the protective layer is less than 2%.

According to some embodiments of the present disclosure, a carbon content of a low dielectric constant material is greater than 10%.

According to some embodiments of the present disclosure, a carbon content of a low dielectric constant material ranges from 10% to 30%.

According to some embodiments of the present disclosure, the protective layer has a first thickness, and the first thickness ranges from 30 nm to 50 nm.

A second aspect of the present disclosure provides a method for manufacturing a semiconductor structure, including the steps as follows.

A target structure is placed in a reaction chamber, and a first reaction gas and a second reaction gas are introduced into the reaction chamber.

A technological condition in the reaction chamber is adjusted to a first technological condition, and a low dielectric constant material layer is formed by the first reaction gas and the second reaction gas on the target structure.

The first technological condition is adjusted to a second technological condition, and a protective layer is formed by the first reaction gas and the second reaction gas on the low dielectric constant material layer.

According to some embodiments of the present disclosure, at least one type of cyclic organosiloxane is included in the first reaction gas, and at least one type of oxygen-containing gas is included in the second reaction gas.

According to some embodiments of the present disclosure, octamethylcyclotetrasiloxane is included in the at least one type of cyclic organosiloxane, and oxygen is included in the at least one type of oxygen-containing gas.

According to some embodiments of the present disclosure, a flow ratio of the first reaction gas to the second reaction gas introduced into the reaction chamber is adjusted while the first technological condition is adjusted to the second technological condition.

According to some embodiments of the present disclosure, that a technological condition in the reaction chamber is adjusted to a first technological condition, and a low dielectric constant material layer is formed by the first reaction gas and the second reaction gas on the target structure includes the steps as follows.

The first reaction gas is introduced into the reaction chamber at a first flow rate, and the second reaction gas is introduced into the reaction chamber at a second flow rate.

A radio frequency source is turned on, so that a first radio frequency power is output by the radio frequency source. An inert gas is introduced, a flow rate of the inert gas is controlled to be a fifth flow rate, and a pressure in the reaction chamber is adjusted to a first pressure. The first reaction gas and the second reaction gas undergo a first chemical reaction, and the reaction product of the first chemical reaction is deposited on the target structure to form the low dielectric constant material layer.

According to some embodiments of the present disclosure, the first radio frequency power includes a low frequency ranging from 45 W to 55 W and a high frequency ranging from 540 W to 660 W; the fifth flow rate ranges from 2200 sccm to 2800 sccm; and the first pressure ranges from 4 Torr to 6 Torr.

According to some embodiments of the present disclosure, the first flow rate ranges from 2500 sccm to 3500 sccm; and the second flow rate ranges from 120 sccm to 180 sccm.

According to some embodiments of the present disclosure, that the first technological condition is adjusted to a second technological condition, and a protective layer is formed by deposition on the low dielectric constant material layer includes the steps as follows.

An output power of the radio frequency source is adjusted to a second radio frequency power, the flow rate of the inert gas is adjusted to a sixth flow rate, and the pressure in the reaction chamber is adjusted to a second pressure; and the first reaction gas is adjusted from the first flow rate to a third flow rate, and the second reaction gas is adjusted from the second flow rate to a fourth flow rate.

The first reaction gas and the second reaction gas undergo a second chemical reaction, and the reaction product of the second chemical reaction is deposited on the low dielectric constant material layer to form the protective layer.

According to some embodiments of the present disclosure, the second radio frequency power includes a low frequency ranging from 80 W to 100 W and a high frequency ranging from 300 W to 500 W; the sixth flow rate ranges from 1500 sccm to 2000 sccm; and the second pressure ranges from 7 Torr to 8 Torr.

According to some embodiments of the present disclosure, the third flow rate ranges from 400 sccm to 500 sccm; and the fourth flow rate ranges from 200 sccm to 500 sccm.

According to some embodiments of the present disclosure, the reaction chamber is maintained under the second technological condition for preset duration, the protective layer with a first thickness is formed on the low dielectric constant material layer, and the first thickness ranges from 30 nm to 50 nm.

According to some embodiments of the present disclosure, a dielectric constant of the low dielectric constant material layer is less than 3.

In the semiconductor structure and the method for manufacturing same provided in the embodiments of the present disclosure, it is unnecessary to transfer the target structure during manufacturing, and the low dielectric constant material layer and the protective layer are formed in the same reaction chamber, which omits one deposition chamber, and further omits a deposition step, improving process efficiency, reducing processing duration, and reducing production costs. The top surface profile of the low dielectric constant material layer can be protected by the protective layer, avoiding formation of a “sharp corner” profile on the top surface of the low dielectric constant material layer during etching.

Other aspects may be understood upon reading and understanding the accompanying drawings and detailed descriptions.

### BRIEF DESCRIPTION OF DRAWINGS

The accompanying drawings, which are incorporated into the specification and constitute a part of the specification, illustrate the embodiments of the present disclosure, and together with the description serve to explain the principles of the embodiments of the present disclosure. In these accompanying drawings, similar reference numerals are adopted to represent similar elements. The accompanying drawings in the following description are some rather than all embodiments of the present disclosure. A person skilled in the art may derive other accompanying drawings from these accompanying drawings without creative efforts.

FIG. 1 is a flowchart of a method for manufacturing a semiconductor structure according to an example embodiment;

FIG. 2 is a flowchart of a method for manufacturing a semiconductor structure according to an example embodiment;

FIG. 3 is a schematic diagram of a target structure according to an example embodiment;

FIG. 4 is a schematic diagram of forming a low dielectric constant material layer according to an example embodiment;

FIG. 5 is a schematic diagram of forming a protective layer according to an example embodiment;

FIG. 6 is a schematic diagram of forming a mask layer according to an example embodiment;

FIG. 7 is a schematic diagram of forming a line groove according to an example embodiment;

FIG. 8 is a schematic diagram of forming a metal line according to an example embodiment;

FIG. 9 is a transmission electron microscope (TEM) scanning diagram of an etched semiconductor structure according to an example embodiment;

FIG. 10 is a transmission electron microscope (TEM) scanning diagram of an etched low dielectric constant material layer according to a comparative embodiment; and

FIG. 11 is a transmission electron microscope (TEM) scanning diagram of etching a low dielectric constant material layer on which an oxide layer is first formed according to a comparative embodiment.

### REFERENCE NUMERALS

1. target structure; 11. semiconductor device layer; 2. reaction chamber; 3. low dielectric constant material layer; 4. protective layer; 5. mask layer; 6. line groove; 7. isolation structure; and 8. metal line.

### DESCRIPTION OF EMBODIMENTS

The technical solutions of the embodiments of the present disclosure are clearly described below with reference to the accompanying drawings of the embodiments of the present disclosure. Clearly, the described embodiments are some rather than all of the embodiments of the present disclosure. Based on the embodiments of the present disclosure, all other embodiments obtained by a person skilled in the art without creative efforts fall within the protection scope of the present disclosure. It should be noted that, in a case of no conflict, the embodiments and the features in the embodiments in the present disclosure may be randomly combined with each other.

In an existing semiconductor structure, to reduce parasitic capacitance between metal lines and improve a response delay caused by the parasitic capacitance, a low dielectric constant material layer is adopted as an interlayer dielectric between the metal lines. A manner of reducing a dielectric constant of the low dielectric constant material layer is usually to introduce a methyl group (—CH3) into a material. However, the methyl group is easily attacked by plasma and breaks, degrading quality of the interlayer dielectric and reliability of the interlayer dielectric between the metal lines.

FIG. 10 is a transmission electron microscope (TEM) scanning diagram of an etched low dielectric constant material layer shown in a comparative embodiment. Referring to FIG. 10, after the low dielectric constant material layer is etched, a “sharp corner” profile is prone to appear on the surface (refer to a region A in FIG. 10). The distance between two adjacent pieces of metal is reduced at the “sharp corner”, causing two adjacent metal lines to be prone to a short circuit (Bridge) problem at the “sharp corner”. In addition, in a process of forming the metal line, a step of filling metal copper (or another metal material) is included. The metal copper is generally grown in an electroplating manner for filling the metal copper. Due to the existence of the “sharp corner”, a top contact angle of the low dielectric constant material layer is relatively large, which is inconducive to growth of the metal copper in an electroplating process.

Therefore, after the low dielectric constant material layer is formed, an oxide layer (e.g., a silicon oxide layer) is generally grown on the surface of the low dielectric constant material layer to protect the top surface profile of the low dielectric constant material layer. FIG. 11 is a transmission electron microscope (TEM) scanning diagram of performing etching after forming an oxide layer on a low dielectric constant material layer in a comparative embodiment. By comparing FIG. 10 with FIG. 11, it can be seen that forming the oxide layer on the low dielectric constant material layer can avoid the “sharp corner” profile at the top of the low dielectric constant material layer after etching is performed (refer to a region B in FIG. 11). In a related technology, a low dielectric constant material layer and an oxide layer are formed in different chambers, and a transition process of a semiconductor structure is included. This increases complexity of a process, and further increases processing duration of the semiconductor structure.

An example embodiment of the present disclosure provides a semiconductor structure and a method for manufacturing same. After a low dielectric constant material layer is formed, it is unnecessary to transfer the semiconductor structure to another chamber, but a protective layer is directly formed on the top surface of the low dielectric constant material layer by adjusting a reaction condition. A material and an oxide of the protective layer have a similar property. The protective layer covers the top surface of the low dielectric constant material layer, so that the top surface profile of the low dielectric constant material layer can be protected, and a “sharp corner” profile can be prevented from appearing on the top surface of the low dielectric constant material layer after etching is performed. In addition, according to the method for manufacturing a semiconductor structure in this embodiment, a process of transferring the semiconductor structure is omitted, and one cavity is omitted, greatly reducing production costs of the semiconductor structure, improving process efficiency, and reducing processing duration (cycle time).

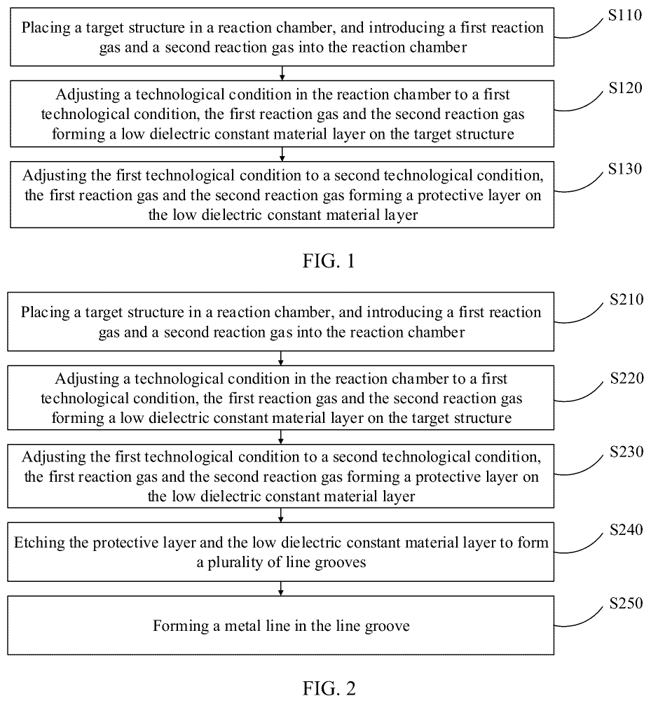

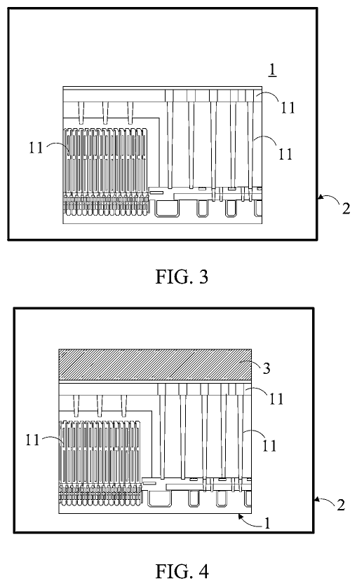

An example embodiment of the present disclosure provides a method for manufacturing a semiconductor structure. As shown in FIG. 1, FIG. 1 is a flowchart of a method for manufacturing a semiconductor structure according to an example embodiment of the present disclosure. FIG. 3 to FIG. 5 are schematic diagrams of stages of a method for manufacturing a semiconductor structure. The method for manufacturing a semiconductor structure is described in the following with reference to FIG. 3 to FIG. 5.

The semiconductor structure is not limited in this embodiment. An example in which the semiconductor structure is a dynamic random access memory (DRAM) is described in the following. However, this embodiment is not limited thereto. The semiconductor structure in this embodiment may be another structure.

As shown in FIG. 1, the example embodiment of the present disclosure provides the method for manufacturing a semiconductor structure, including the following steps:

In the step of S110, a target structure is placed in a reaction chamber, and a first reaction gas and a second reaction gas are introduced into the reaction chamber.

As shown in FIG. 3, a target structure 1 may include a wafer. The wafer is a semiconductor wafer, for example, may be a silicon (Si) wafer, a germanium (Ge) wafer, a germanium silicon (SiGe) wafer, a silicon on insulator (SOI) wafer, or a germanium on insulator (GOI) wafer. The semiconductor wafer may be further a wafer including another element semiconductor or compound semiconductor, e.g., gallium arsenide (GaAs), indium phosphide (InP), or silicon carbide (SiC). The semiconductor wafer may be further a stacked structure, for example, the semiconductor wafer is a stacked structure formed by a silicon wafer and a germanium silicon wafer.

The target structure 1 may further include another epitaxial structure, e.g., silicon germanium on insulator (SGOI).

The target structure 1 may further include one or more layers of stacked semiconductor device layers 11, and the semiconductor device layer 11 may be formed in a wafer or disposed on a wafer. Multiple semiconductor devices and multiple metal interconnection structures may be disposed at each semiconductor device layer 11. At least one of a metal oxide semiconductor field effect transistor, a bipolar junction transistor, a resistor, an inductor, a diode, and an optical component may be included in the semiconductor device.

As shown in FIG. 3, after the target structure 1 is placed in the reaction chamber 2, air in the reaction chamber 2 is drawn out, and a vacuum state is formed in the reaction chamber 2. Then, a carrier gas is introduced into the reaction chamber 2, and the intensity of pressure in the reaction chamber 2 is adjusted by adjusting parameters such as a flow rate of the carrier gas, so that the reaction chamber 2 is in a low pressure state. In this embodiment, a low pressure state means that the pressure in the reaction chamber 2 is less than 10 Torr. The carrier gas is an inert gas, for example, the carrier gas may be helium.

Then, the first reaction gas and the second reaction gas are introduced into the reaction chamber 2, and the first reaction gas and the second reaction gas may be separately introduced into the reaction chamber 2. Alternatively, the first reaction gas and the second reaction gas may be mixed in proportion outside the reaction chamber 2, and then a mixed gas is introduced into the reaction chamber 2. While the mixed gas is introduced into the reaction chamber 2, a cooling apparatus may be adopted to cool a gas path configured to transport the mixed gas, to avoid reaction between the first reaction gas and the second reaction gas in the gas path.

In the reaction chamber, the first reaction gas and the second reaction gas are processed according to a plasma enhanced chemical vapor deposition (PECVD) method. A dielectric material layer 3 (described in detail in subsequent steps) and a protective layer 4 (described in detail in subsequent steps) are formed by deposition on the target structure 1. The first reaction gas may be a silicon source gas, and the second reaction gas may be an oxygen source gas.

In the step of S120, a technological condition in the reaction chamber is adjusted to a first technological condition, and a low dielectric constant material layer is formed by the first reaction gas and the second reaction gas on the target structure.

Referring to FIG. 3, in the first technological condition, the first reaction gas and the second reaction gas react with each other and are deposited to grow a low dielectric constant material on the target structure 1. After growth ends, as shown in FIG. 4, the low dielectric constant material layer 3 is formed on the target structure 1.

The thickness of the low dielectric constant material layer 3 is set according to a process requirement. Duration in which the low dielectric constant material is grown by the first reaction gas and the second reaction gas on the target structure 1 is controlled according to the thickness of the low dielectric constant material layer 3.

A silicon element and an oxygen element are included in the material of the low dielectric constant material layer 3 formed in this embodiment, and a dielectric constant of the material of the low dielectric constant material layer 3 is less than 3.

In the step of S130, the first technological condition is adjusted to a second technological condition, and a protective layer is formed by the first reaction gas and the second reaction gas on the low dielectric constant material layer.

Referring to FIG. 4, after growth of the low dielectric constant material layer 3 ends, the carrier gas, the first reaction gas, and the second reaction gas are continuously introduced into the reaction chamber 2. Simultaneously, the technological condition in the reaction chamber 2 is adjusted, and the first technological condition is adjusted to the second technological condition. The second technological condition and the first technological condition are different. It may be understood that, while the first technological condition is adjusted to the second technological condition, the flow rate of the first reaction gas and the flow rate of the second reaction gas may be adjusted, so that the flow ratio of the first reaction gas to the second reaction gas introduced into the reaction chamber 2 is adjusted.

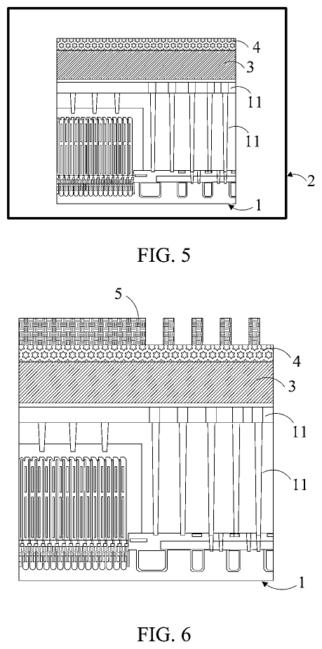

In the reaction chamber 2, the first reaction gas and the second reaction gas react with each other and are deposited under the second technological condition. As shown in FIG. 5, the protective layer 4 is grown on the top surface of the low dielectric constant material layer 3. The material component of the protective layer 4 is similar to the material component of the low dielectric constant material layer 3, and both include a silicon element and an oxygen element. However, the material property of the protective layer 4 is different from the material property of the low dielectric constant material layer 3, and the property of the protective layer 4 is similar to that of an oxide (e.g., silicon oxide). The protective layer 4 covers the top surface of the low dielectric constant material layer 3, avoiding damage to the low dielectric constant material layer 3 during subsequent etching. In addition, the protective layer 4 can avoid forming a “sharp corner” profile on the top surface of the low dielectric constant material layer 3 when the low dielectric constant material layer 3 is etched.

According to the method for manufacturing a semiconductor structure in this embodiment, a process technology of the low dielectric constant material layer 3 is optimized. After the low dielectric constant material layer 3 is formed in the reaction chamber 2, the technological condition in the reaction chamber 2 is adjusted. The protective layer 4 is grown in situ and formed on the low dielectric constant material layer 3, and the top surface profile of the low dielectric constant material layer 3 is protected by the protective layer 4, to avoid forming the “sharp corner” profile on the top surface of the low dielectric constant material layer 3 after etching is performed. According to the method for manufacturing a semiconductor structure in this embodiment, the low dielectric constant material layer 3 and the protective layer 4 may be formed in the same reaction chamber 2 without a need of transferring the target structure 1. Therefore, a step of forming an oxide layer by deposition on the low dielectric constant material layer 3 is omitted, and a chamber for depositing the oxide layer on the low dielectric constant material layer 3 is omitted, improving process efficiency, reducing processing duration, and reducing production costs.

According to an example embodiment, this embodiment is a description of the foregoing embodiment. In this embodiment, at least one type of cyclic organosiloxane is included in the first reaction gas, and at least one type of oxygen-containing gas is included in the second reaction gas.

A compound having one or more silicon-carbon bonds is included in the cyclic organosiloxane. A cyclic organosiloxane compound having one or more rings may be adopted, each ring has alternating silicon and oxygen atoms, and each ring has one or more alkyl groups bonded to silicon atoms.

For example, the cyclic organosiloxane may be selected from at least one of the following compounds: 1, 3, 5, 7-tetramethylcyclotetra-Siloxane (TMCTS), —(—SiHCH3-O-)4-(cyclic), octamethylcyclotetrasiloxane (OMCTS), —(—Si(CH3)2-O-)4-(cyclic), 1, 3, 5, 7, 9-pentamethylcyclopentasiloxane, —(—SiHCH3-O-)5-(cyclic), hexamethylcyclotrisiloxane, —(—Si(CH3)2-O-)3-(cyclic), and decamethylcyclopentasiloxane, —(—Si(CH3)2-O-)5-(cyclic). It may be understood that selection of the at least one type of cyclic organosiloxane is not limited to this example.

The oxygen-containing gas may be provided in any suitable form of a gas containing molecular oxygen. For example, molecular oxygen, such as oxygen or ozone, may be provided directly; or air is provided.

Referring to FIG. 5, a silicon oxide-carbon material is included in the material of the low dielectric constant material layer 3 grown by the first reaction gas and the second reaction gas under the first technological condition. A methyl group (—CH3) is included in the material of the low dielectric constant material layer 3, so that the dielectric constant of the dielectric material layer 3 can be further reduced.

A carbon-doped silicon oxide material is included in the material of the protective layer 4 grown by the first reaction gas and the second reaction gas under the second technological condition. The oxygen content of the material of the protective layer 4 is higher than the oxygen content of the material of the low dielectric constant material layer 3. The carbon content of the material of the protective layer 4 is less than the carbon content of the material of the low dielectric constant material layer 3.

In this embodiment, the at least one type of cyclic organosiloxane and the at least one type of oxygen-containing gas are adopted as gas sources. The low dielectric constant material layer 3 is formed by the at least one type of cyclic organosiloxane and the at least one type of oxygen-containing gas under the first technological condition. The dielectric constant of the low dielectric constant material layer 3 is lower, and the low dielectric constant material layer 3 serves as an interlayer dielectric, so that coupling capacitance between semiconductor devices can be further reduced, and a response speed of the semiconductor structure can be increased, thereby facilitating further reduction of the feature size of the semiconductor structure. The protective layer 4 is formed by the at least one type of cyclic organosiloxane and the at least one type of oxygen-containing gas under the second technological condition. The protective layer 4 covers the top surface of the low dielectric constant material layer 3, to protect the top surface profile of the low dielectric constant material layer 3, and further avoid forming the “sharp corner” profile on the top surface of the low dielectric constant material layer 3 in a process of etching the low dielectric constant material layer 3.

An example embodiment of the present disclosure provides a method for manufacturing a semiconductor structure. As shown in FIG. 2, FIG. 2 is a flowchart of a method for manufacturing a semiconductor structure according to an example embodiment of the present disclosure. FIG. 3 to FIG. 8 are schematic diagrams of stages of a method for manufacturing a semiconductor structure. The method for manufacturing a semiconductor structure is described in the following with reference to FIG. 3 to FIG. 8.

As shown in FIG. 2, the example embodiment of the present disclosure provides the method for manufacturing a semiconductor structure, including the following steps:

In the step of S210, a target structure is placed in a reaction chamber, and a first reaction gas and a second reaction gas are introduced into the reaction chamber.

As shown in FIG. 3, first, a target structure 1 is provided, and the target structure 1 is a wafer. A semiconductor device layer 11 is provided in the target structure 1, and multiple semiconductor devices are disposed at each semiconductor device layer 11. The wafer and the semiconductor device layer 11 in this embodiment are the same as the wafer and the semiconductor device layer 11 in the foregoing embodiment. Details are not described herein again.

Then, the target structure 1 is transferred to a reaction chamber 2, and the reaction chamber 2 is drawn to a vacuum state. In this embodiment, the reaction chamber 2 is a low-pressure chemical vapor deposition chamber.

Then, a first reaction gas and a second reaction gas are separately introduced into the reaction chamber 2, at least one type of cyclic organosiloxane is included in the first reaction gas, and at least one type of oxygen-containing gas is included in the second reaction gas. In this embodiment, octamethylcyclotetrasiloxane is included in the at least one type of cyclic organosiloxane, and oxygen is included in the at least one type of oxygen-containing gas.

In the step of S220, a technological condition in the reaction chamber is adjusted to a first technological condition, and a low dielectric constant material layer is formed by the first reaction gas and the second reaction gas on the target structure.

That a technological condition in the reaction chamber 2 is adjusted to the first technological condition includes the following:

First, the temperature in the reaction chamber 2 is adjusted to 350° C. to 400° C.

Then, the first reaction gas is introduced into the reaction chamber 2 at a first flow rate, and the second reaction gas is introduced into the reaction chamber 2 at a second flow rate.

The first flow rate ranges from 2500 sccm to 3500 sccm. For example, the first flow rate may be 2500 sccm, 2700 sccm, 2900 sccm, 3000 sccm, 3100 sccm, 3300 sccm, or 3500 sccm.

The second flow rate ranges from 120 sccm to 180 sccm. For example, the second flow rate may be 120 sccm, 130 sccm, 140 sccm, 150 sccm, 160 sccm, 170 sccm, or 180 sccm.

Then, a radio frequency source is turned on, so that a first radio frequency power is output by the radio frequency source. An inert gas is introduced into the reaction chamber 2, the flow rate of the inert gas is controlled to be a fifth flow rate, and the pressure in the reaction chamber 2 is adjusted to a first pressure. The first reaction gas and the second reaction gas undergo a first chemical reaction, and the reaction product of the first chemical reaction is deposited on the target structure 1 to form a low dielectric constant material layer 3.

The radio frequency source is a pulse radio frequency source, and the first radio frequency power is output by a radio frequency source pulse. Alternatively, the radio frequency source is a continuous wave radio frequency source, and the first radio frequency power is continuously output by the radio frequency source.

In this embodiment, a high-frequency radio frequency source and a low-frequency radio frequency source are included in the radio frequency source. Both the high-frequency radio frequency source and the low-frequency radio frequency source are pulse radio frequency sources. The radio frequency power of the high-frequency radio frequency source has a high frequency ranging from 540 W to 660 W. The radio frequency power of the low-frequency radio frequency source has a low-frequency ranging from 45 W to 55 W. Uniformity of the low dielectric constant material layer 3 formed by deposition can be improved by the phase difference between the high-frequency power and the low-frequency power of the first radio frequency power, so that the thickness of the formed low dielectric constant material layer 3 is uniform. Therefore, problems, for example, that the thickness of the low dielectric constant material layer 3 formed in the center region of the target structure 1 is greater than the thickness of the low dielectric constant material layer 3 in an edge region of the target structure 1, are avoided, thereby further improving quality of the low dielectric constant material layer 3.

The inert gas is introduced into the reaction chamber 2, and an inert atmosphere is provided by the inert gas for subsequent formation of the low dielectric constant material layer 3 and a protective layer 4 (which is described in detail in subsequent steps). In this embodiment, helium is included in the inert gas, and the fifth flow rate ranges from 2200 sccm to 2800 sccm.

In addition, the pressure in the reaction chamber 2 is adjusted to a first pressure by adjusting the fifth flow rate of the inert gas, and the first pressure ranges from 4 Torr to 6 Torr. For example, the pressure in the reaction chamber 2 may be adjusted to 4 Torr, 4.3 Torr, 4.5 Torr, 4.8 Torr, 5 Torr, 5.3 Torr, 5.7 Torr, or 6 Torr. It may be understood that, in a process of the first reaction gas and the second reaction gas undergoing the first chemical reaction, the pressure in the reaction chamber 2 may be fluctuating or changing. When the pressure in the reaction chamber 2 fluctuates or changes, the fifth flow rate of the inert gas is adjusted in real time to maintain the pressure in the reaction chamber 2 within a range of the first pressure. It is not limited to maintaining the pressure in the reaction chamber 2 at a specified pressure value.

A low dielectric constant material is formed by the first reaction gas, the second reaction gas, and the inert gas under the first technological condition according to a plasma enhanced chemical vapor deposition method. The moving direction of the low dielectric constant material is guided by the first radio frequency power, so that the low dielectric constant material is grown on the surface of the target structure 1 to form the low dielectric constant material layer 3. Therefore, deposition of the low dielectric constant material can be promoted, and formation of the low dielectric constant material layer 3 can be accelerated.

A silicon oxide-carbon material is included in the material of the low dielectric constant material layer 3 formed by the first reaction gas and the second reaction gas on the top surface of the target structure 1. A dielectric constant of the low dielectric constant material layer 3 is less than 3. For example, silicon oxycarbide (SiOC) is included in the material of the low dielectric constant material layer 3.

In the step of S230, the first technological condition is adjusted to a second technological condition, and a protective layer is formed by the first reaction gas and the second reaction gas on the low dielectric constant material layer.

In this embodiment, the first technological condition is adjusted to the second technological condition, and the following implementation may be adopted.

Referring to FIG. 4, the temperature in the reaction chamber 2 remains unchanged from 350° C. to 400° C., the output power of the radio frequency source is adjusted to a second radio frequency power, the flow rate of the inert gas is adjusted to a sixth flow rate, and the pressure in the reaction chamber 2 is adjusted to a second pressure. In addition, the first reaction gas is adjusted from the first flow rate to a third flow rate, and the second reaction gas is adjusted from the second flow rate to a fourth flow rate.

By adjusting the radio frequency source, the radio frequency source changes from outputting the first radio frequency power to outputting the second radio frequency power. The second radio frequency power has a low frequency ranging from 80 W to 100 W and a high frequency ranging from 300 W to 500 W. While the radio frequency power output by the radio frequency source is adjusted, the flow rate of the inert gas is adjusted to the sixth flow rate. The sixth flow rate ranges from 1500 sccm to 2000 sccm. The pressure in the reaction chamber 2 is adjusted from the first pressure to the second pressure. The second pressure ranges from 7 Torr to 8 Torr. For example, the pressure in the reaction chamber 2 may be adjusted to 7 Torr, 7.2 Torr, 7.4 Torr, 7.5 Torr, 7.6 Torr, 7.8 Torr, 7.9 Torr, or 8 Torr. It may be understood that, in a process of the first reaction gas and the second reaction gas undergoing a second chemical reaction, the flow rate of the inert gas is adjusted in real time, so that the pressure in the reaction chamber 2 is maintained in the range of the second pressure.

The first reaction gas is adjusted from the first flow rate to the third flow rate, and the second reaction gas is adjusted from the second flow rate to the fourth flow rate, so that the flow rate of the first reaction gas introduced into the reaction chamber 2 can be reduced, and the flow rate of the second reaction gas introduced into the reaction chamber 2 can be increased. In this case, the content of octamethylcyclotetrasiloxane in the reaction chamber 2 is reduced, and the content of oxygen in the reaction chamber 2 is increased, so that the reaction product of the second chemical reaction between the first reaction gas and the second reaction gas has a higher oxygen content.

The third flow rate ranges from 400 sccm to 500 sccm. The fourth flow rate ranges from 200 sccm to 500 sccm. For example, the third flow rate may be 400 sccm, 420 sccm, 450 sccm, 460 sccm, 470 sccm, 480 sccm, or 500 sccm. The fourth flow rate may be 200 sccm, 250 sccm, 300 sccm, 350 sccm, 400 sccm, 450 sccm, or 500 sccm.

As shown in FIG. 5, in the second technological condition, the first reaction gas and the second reaction gas undergo the second chemical reaction, and the reaction product of the second chemical reaction is deposited on the low dielectric constant material layer 3 to form the protective layer 4. A carbon-doped silicon oxide material is mainly included in the material of the protective layer 4. In this embodiment, a silicon oxycarbide (SiOC) composite material is included in the material of the protective layer 4. An oxygen element content in the material of the protective layer 4 is higher than an oxygen element content in the material of the low dielectric constant material layer 3. The content of carbon elements in the material of the protective layer 4 is lower than the content of carbon elements in the material of the low dielectric constant material layer 3. The material property of the protective layer 4 formed in this embodiment is similar to the property of silicon oxide. In addition, a dielectric constant of the material of the protective layer 4 is lower than a dielectric constant of silicon oxide.

In some embodiments, to increase the oxygen content of the material of the formed protective layer 4, to enable the property of the protective layer 4 to be closer to that of silicon oxide, and further improve the protection effect of the protective layer 4 on the top surface profile of the low dielectric constant material layer 3, the proportion of the second reaction gas in the reaction chamber 2 is increased in a process of forming the protective layer 4. For example, the flow ratio of the first reaction gas to the second reaction gas may be set to 1. Alternatively, the flow ratio of the first reaction gas to the second reaction gas is set to be less than 1.

In some embodiments, the reaction chamber 2 is maintained under the second technological condition for preset duration. The protective layer 4 with a first thickness is formed on the low dielectric constant material layer 3, and the first thickness ranges from 30 nm to 50 nm. For example, the first thickness may be 30 nm, 35 nm, 40 nm, 45 nm, or 50 nm.

When the thickness of the protective layer 4 ranges from 30 nm to 50 nm, the protective layer 4 covers the top surface of the low dielectric constant material layer 3, which is sufficient to prevent the low dielectric constant material layer 3 from being damaged in a subsequent technological process. For example, in a process of patterning the low dielectric constant material layer 3, the low dielectric constant material layer 3 is generally etched by an etching process. The thickness of the protective layer 4 ranging from 30 nm to 50 nm can provide adequate protection for the low dielectric constant material layer 3, avoid excessive etching of the low dielectric constant material layer 3 covered by the protective layer 4, and avoid forming a “sharp corner” profile on the top surface of the low dielectric constant material layer 3, thereby improving precision of patterning the low dielectric constant material layer 3 and controllability of the process, avoiding adverse impact of the “sharp corner” profile on the semiconductor structure, and improving reliability of the semiconductor structure. In addition, the thickness of the protective layer 4 within this range can avoid that the thickness of the protective layer 4 is too thick, which affects the effect of reducing coupling capacitance by the low dielectric constant material layer 3, so that the semiconductor structure has a faster response speed.

According to the method for manufacturing a semiconductor structure in this embodiment, the property of the protective layer 4 formed on the low dielectric constant material layer 3 is closer to that of silicon oxide, and the protective layer 4 has a better effect on protecting the low dielectric constant material layer 3 instead of oxide. In addition, the dielectric constant of the material of the protective layer 4 is lower than the dielectric constant of silicon oxide, and coupling capacitance between devices in the semiconductor structure can be better reduced by the protective layer 4.

According to an example embodiment, this embodiment includes all steps of the foregoing embodiment. The difference between this embodiment and the foregoing embodiment lies in that after step S230, the following steps are further included.

In the step of S240, the protective layer and the low dielectric constant material layer are etched to form multiple line grooves.

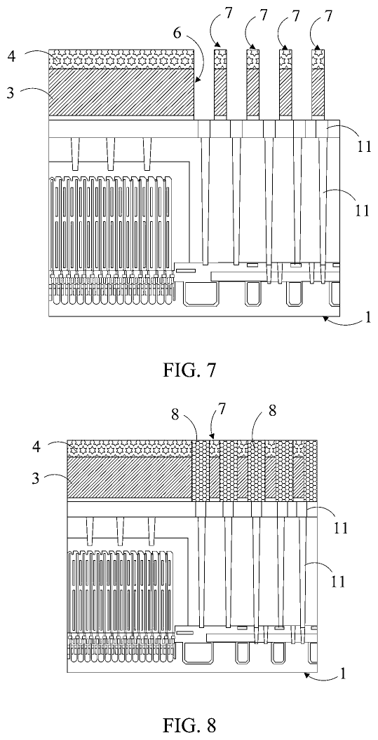

As shown in FIG. 6, a mask layer 5 is formed on the top surface of the protective layer 4, and a part of the top surface of the protective layer 4 is exposed by the mask layer 5. Based on the mask layer 5, the protective layer 4 and the low dielectric constant material layer 3 are sequentially etched, and the protective layer 4 and the low dielectric constant material layer 3 that are exposed by the mask layer 5 are removed. As shown in FIG. 7, multiple independently disposed line grooves 6 are formed, and the top surface of the target structure 1 is exposed by the line grooves 6. The protective layer 4 and the low dielectric constant material layer 3 are divided by the multiple line grooves 6 into multiple isolation structures 7. The isolation structure 7 is disposed between two adjacent line grooves 6. The low dielectric constant material layer 3 located on the target structure 1 and the protective layer 4 covering the top surface of the low dielectric constant material layer 3 are included in each isolation structure 7. The etching process may be a dry process or a wet process.

In a process of forming the multiple line grooves 6, the protective layer 4 exposed by the mask layer 5 is first removed, to expose a part of the top surface of the low dielectric constant material layer 3. Then, the low dielectric constant material layer 3 exposed by the protective layer 4 is etched. In a process of etching the low dielectric constant material layer 3, the protective layer 4 plays a good masking effect, preventing the low dielectric constant material layer 3 covered by the protective layer 4 from being removed or damaged by the etching process, to limit the range of etching the low dielectric constant material layer 3 to the region exposed by the protective layer 4, so that the morphology and the feature size of the formed line groove 6 are more in line with expectations. As shown in FIG. 7, in the cross-section perpendicular to the top surface of the target structure 1, the width of each isolation structure 7 divided by the line groove 6 is consistent from top to bottom, and the retained top of the low dielectric constant material layer 3 has no profile defect such as the “sharp corner”. Therefore, the isolation structure 7 has a good isolation effect.

In the step of S250, a metal line is formed in the line groove.

As shown in FIG. 8, referring to FIG. 7, a metal conductive material is deposited to fill the line groove 6. One metal line 8 is formed in each line groove 6, and adjacent metal lines 8 are separated from each other by the isolation structure 7.

As shown in FIG. 8, in the cross-section perpendicular to the top surface of the target structure 1, the width of each isolation structure 7 is consistent from top to bottom (that is, in the vertical direction shown in FIG. 8). Therefore, there is a good isolation effect. Because the dielectric constant of the low dielectric constant material layer 3 is less than 3, coupling capacitance between adjacent metal lines 8 can be effectively reduced. In addition, the protective layer 4 has a lower dielectric constant than the oxide, so that coupling capacitance between top ends of the two adjacent metal lines 8 can be further reduced, the problem of a response delay of the semiconductor structure is further improved, and a response quantity of the semiconductor structure is increased, thereby improving performance and reliability of the semiconductor structure.

Specific embodiments of this example embodiment are listed in the following.

Table 1 shows specific parameters of the low dielectric constant material layer 3 formed in the method for manufacturing a semiconductor structure in this example embodiment. Table 2 shows specific parameters of the protective layer 4 formed in the method for manufacturing a semiconductor structure in this example embodiment. It should be noted that specific parameters of the method for manufacturing a semiconductor structure in the present disclosure are not limited to the data in Table 1 and Table 2.

TABLE 1
Specific embodiment of forming a low dielectric constant material layer

| | | | | | First radio | First radio | |
|---|---|---|---|---|---|---|---|
| | | | | | frequency | frequency | |
| First | Second | First | Second | Fifth | power - low | power - high | First |
| reaction | reaction | flow rate | flow rate | flow rate | frequency | frequency | pressure |
| gas | gas | (sccm) | (sccm) | (sccm) | (W) | (W) | (Torr) |
| OMCTS | O₂ | 3000 | 150 | 2500 | 50 | 600 | 5 |

TABLE 2
Specific embodiment of forming a protective layer

| | | | | | Second radio | Second radio | |
|---|---|---|---|---|---|---|---|
| | | | | | frequency | frequency | |
| First | Second | Third | Fourth | Sixth | power - low | power - high | Second |
| reaction | reaction | flow rate | flow rate | flow rate | frequency | frequency | pressure |
| gas | gas | (sccm) | (sccm) | (sccm) | (W) | (W) | (Torr) |
| OMCTS | O₂ | 4000 | 200 | 1500 | 90 | 300 | 7 |

OMCTS is octamethylcyclotetrasiloxane.

The semiconductor structure manufactured according to the method for manufacturing a semiconductor structure in the foregoing embodiment is tested. The content of each component of the low dielectric constant material layer 3 and the protective layer 4 is shown in Table 3. In this embodiment, the content of each component of the low dielectric constant material layer 3 and the protective layer 4 is expressed in mass percentage.

TABLE 3
Component table of the material of a semiconductor structure

| Carbon | Oxygen | Silicon | | | |
|---|---|---|---|---|---|
| element | element | element | | | |
| content | content | content | Carbon | Oxygen | Silicon |
| of a low | of the low | of the low | element | element | element |
| dielectric | dielectric | dielectric | content | content | content |
| constant | constant | constant | of a | of the | of the |
| material | material | material | protective | protective | protective |
| layer (%) | layer (%) | layer (%) | layer (%) | layer (%) | layer (%) |
| 27.2 | 41.6 | 31.2 | 1.02 | 64.9 | 34.1 |

According to the method for manufacturing a semiconductor structure in the foregoing embodiment, a semiconductor structure in Embodiments 1-5 is manufactured, and performance of a protective layer 4 of the semiconductor structure in Embodiments 1-5 is tested. An oxide layer is formed by deposition on the low dielectric constant material layer 3. A semiconductor structure in Comparative Embodiments 1-5 is manufactured, and performance of the oxide layer in the semiconductor structure in Comparative Embodiments 1-5 is tested. Performance test results are shown in Table 4.

TABLE 4
Performance test results of a protective layer in Embodiments
1-5 and an oxide in Comparative Embodiments 1-5

| | | Film | Overlay | Feature size | |
|---|---|---|---|---|---|
| | Film | uniformity/ | error/ | uniformity/ | Wafer |
| | thickness | U % | OVL | U % | defect |
| Embodiment | 200.7 | 2.14% | 1.98 | 3.33% | 1.74% |
| 1 | | | | | |
| Embodiment | 199.6 | 2.28% | 1.55 | 3.51% | 1.22% |
| 2 | | | | | |
| Embodiment | 201.1 | 2.79% | 1.57 | 3.28% | 1.39% |
| 3 | | | | | |
| Embodiment | 199.4 | 2.64% | 1.32 | 3.92% | 1.17% |
| 4 | | | | | |
| Embodiment | 199 | 2.94% | 1.79 | 3.71% | 1.81% |
| 5 | | | | | |
| Comparative | 203 | 2.80% | 2.03 | 3.27% | 1.37% |
| Embodiment | | | | | |
| 1 | | | | | |
| Comparative | 202.4 | 2.73% | 1.91 | 3.15% | 1.29% |
| Embodiment | | | | | |
| 2 | | | | | |
| Comparative | 201.8 | 2.97% | 1.62 | 3.88% | 1.99% |
| Embodiment | | | | | |
| 3 | | | | | |
| Comparative | 199.4 | 2.61% | 1.54 | 3.91% | 1.11% |
| Embodiment | | | | | |
| 4 | | | | | |
| Comparative | 198.2 | 2.44% | 1.69 | 3.21% | 1.48% |
| Embodiment | | | | | |
| 5 | | | | | |

It may be learned from data of the performance test results recorded in Table 4 that the performance test result of the protective layer 4 in the semiconductor structure in Embodiments 1-5 is similar to the performance test result of the oxide layer in Comparative Embodiments 1-5. Therefore, there is no obvious defect in replacing the oxide layer by the protective layer 4, the low dielectric constant material layer 3 can be protected by the protective layer 4 instead of the oxide layer, and a good replacement effect is implemented.

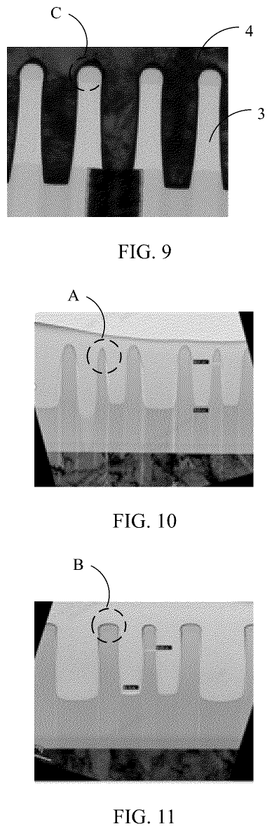

After etching processing is performed on the semiconductor structure formed in this embodiment, a transmission electron microscope scanning is performed on the semiconductor structure formed in this embodiment. A scanning structure is shown in FIG. 9. Referring to FIG. 9, in the semiconductor structure formed in this embodiment, the protective layer 4 covers the low dielectric constant material layer 3, and no “sharp corner” profile appears on the top surface of the low dielectric constant material layer 3 after etching is performed (referring to a region C in FIG. 9). The top surface profile of the semiconductor structure is good. In this embodiment, the protective layer 4 is formed on the low dielectric constant material layer 3 to replace the oxide layer, so that the effect of protecting the top surface profile of the low dielectric constant material layer 3 can also be implemented, to avoid the problem of reducing spacing of the top surface of a trench formed through etching in the semiconductor structure, thereby avoiding a short circuit of a conductive structure formed in the trench and improving yield and electrical performance of the semiconductor structure.

According to an example embodiment, a semiconductor structure is provided. As shown in FIG. 5, FIG. 6, FIG. 7, or FIG. 8, the semiconductor structure includes the target structure 1, the low dielectric constant material layer 3 disposed on the target structure 1, and the protective layer 4 disposed on the low dielectric constant material layer 3. The low dielectric constant material layer 3 and the protective layer 4 are prepared from the same precursor, and the protective layer 4 has a lower carbon content. A dielectric constant of the material of the low dielectric constant material layer 3 is less than 3.

In some embodiments, a silicon oxide-carbon material is included in the material of the low dielectric constant material layer 3. A silicon oxide-carbon material is included in the material of the protective layer 4.

The material of the protective layer 4 is similar in composition to the material of the low dielectric constant material layer 3. However, an oxygen content in the protective layer 4 is greater than an oxygen content in the low dielectric constant material layer 3, a carbon content in the protective layer 4 is less than a carbon content in the low dielectric constant material layer 3, and the property of the protective layer 4 is different from the property of the low dielectric constant material layer 3. The property of the protective layer 4 is closer to that of oxide. The protective layer 4 is disposed on the low dielectric constant material layer 3, has a good masking effect, and improves and protects the top surface profile of the low dielectric constant material layer 3, so that the low dielectric constant material layer 3 can be disposed between semiconductor devices as an interlayer dielectric, to reduce coupling capacitance between the semiconductor devices, increase a response speed of the semiconductor structure, and improve yield and reliability of the semiconductor structure.

In some embodiments, at least one type of cyclic organosiloxane is included in the precursor.

In some embodiments, octamethylcyclotetrasiloxane is included in the at least one type of cyclic organosiloxane.

In some embodiments, the silicon oxide-carbon material is included in the material of the low dielectric constant material layer, and a carbon-doped silicon oxide material is included in the material of the protective layer.

In some embodiments, the carbon content of the protective layer is less than 5%.

In some embodiments, the carbon content of the protective layer is less than 2%.

In some embodiments, a carbon content of a low dielectric constant material is greater than 10%.

In some embodiments, a carbon content of a low dielectric constant material ranges from 10% to 30%.

In some embodiments, the protective layer has a first thickness, and the first thickness ranges from 30 nm to 50 nm. For example, the first thickness may be 30 nm, 35 nm, 40 nm, 45 nm, or 50 nm. The thickness of the protective layer 4 within this range is enough to provide good protection for the low dielectric constant material layer 3, and improve and protect the top surface profile of the low dielectric constant material layer. In addition, the thickness of the protective layer 4 within this range can avoid that the thickness of the protective layer 4 is too thick, which affects the effect of reducing coupling capacitance by the low dielectric constant material layer 3, so that the semiconductor structure has a faster response speed.

The semiconductor structure in this embodiment may be a memory chip, and the memory chip may be adopted in a dynamic random access memory (DRAM). However, the memory chip may alternatively be applied to a static random access memory (SRAM), a flash memory (a flash EPROM), a ferroelectric random access memory (FRAM), a magnetic random access memory (MRAM), a phase-change random access memory (PRAM), or the like.

The embodiments and the implementations in this specification are described in a progressive manner. Each embodiment focuses on a difference from other embodiments. Refer to the embodiments for same or similar parts in the embodiments.

In the descriptions of this specification, descriptions with reference to terms “embodiment”, “example embodiment”, “some implementations”, “example implementation”, “example”, and the like means that specific features, structures, materials, or characteristics described with reference to implementations or examples are included in at least one implementation or example of the present disclosure.

In this specification, a schematic description of the foregoing term does not necessarily refer to a same implementation or an example. Further, specific features, structures, materials, or characteristics described may be properly combined in any one or more implementations or examples.

In descriptions of the present disclosure, it should be noted that an orientation or positional relationship indicated by terms “center”, “up”, “down”, “left”, “right”, “vertical”, “horizontal”, “inner”, “outer”, and the like, is based on the orientation or positional relationship shown in accompanying drawings, and is only for case of describing the present disclosure and simplifying the descriptions, rather than indicating or implying that an apparatus or a component referred to must have a specific orientation, be constructed and operated in a specific orientation, which therefore cannot be understood as a limitation to the present disclosure.

It may be understood that the terms “first”, “second” and the like adopted in the present disclosure may be adopted to describe various structures in the present disclosure, but these structures are not limited to these terms. These terms are adopted only to distinguish a first structure from another structure.

In one or more of the accompanying drawings, the same elements are represented by similar reference numerals. For clarity, multiple parts in the accompanying drawings are not drawn in scale. In addition, some well-known parts may not be shown. For simplicity, a structure obtained after several steps may be described in one diagram. Many specific details of the present disclosure, e.g., the structure, material, size, processing technique, and technology of the device, are described below for a clearer understanding of the present disclosure. However, as can be understood by a person skilled in the art, the present disclosure may not be implemented according to these specific details.

Finally, it should be noted that the foregoing embodiments are merely intended to describe the technical solutions of the present disclosure, and are not intended to limit the present disclosure. Although the present disclosure is described in detail with reference to the foregoing embodiments, persons skilled in the art should understand that they may still make modifications to the technical solutions described in the foregoing embodiments or make equivalent replacements to some or all technical features thereof. However, these modifications or replacements do not make the essence of the corresponding technical solutions depart from the scope of the technical solutions in the embodiments of the present disclosure.

### INDUSTRIAL APPLICABILITY

In the semiconductor structure and the method for manufacturing same provided in the embodiments of the present disclosure, it is unnecessary to transfer the target structure during manufacturing, and the low dielectric constant material layer and the protective layer are formed in the same reaction chamber, which omits one deposition chamber, and further omits a deposition step, improving process efficiency, reducing processing duration, and reducing production costs. The top surface profile of the low dielectric constant material layer can be protected by the protective layer, avoiding the formation of the “sharp corner” profile on the top surface of the low dielectric constant material layer during etching.

What is claimed is:

1. A semiconductor structure, comprising a target structure, and further comprising:
a low dielectric constant material layer, disposed on the target structure; and
a protective layer, disposed on the low dielectric constant material layer; and, wherein
the low dielectric constant material layer and the protective layer are prepared from a same precursor, and the protective layer having a lower carbon content.

2. The semiconductor structure according to claim 1, wherein the precursor comprises at least one type of cyclic organosiloxane.

3. The semiconductor structure according to claim 2, wherein the at least one type of cyclic organosiloxane comprises octamethylcyclotetrasiloxane.

4. The semiconductor structure according to claim 1, wherein a dielectric constant of the low dielectric constant material layer is less than 3.

5. The semiconductor structure according to claim 1, wherein a material of the low dielectric constant material layer comprises a silicon oxide-carbon material, and a material of the protective layer comprises a carbon-doped silicon oxide material.

6. The semiconductor structure according to claim 5, wherein a carbon content of the protective layer is less than 5%; and preferably, the carbon content of the protective layer is less than 2%.

7. The semiconductor structure according to claim 5, wherein a carbon content of the low dielectric constant material layer is greater than 10%; and preferably, the carbon content of the low dielectric constant material layer ranges from 10% to 30%.

8. The semiconductor structure according to claim 1, wherein the protective layer has a first thickness, and the first thickness ranges from 30 nm to 50 nm.

9. A method for manufacturing a semiconductor structure, comprising:
placing a target structure in a reaction chamber, and introducing a first reaction gas and a second reaction gas into the reaction chamber;
adjusting a technological condition in the reaction chamber to a first technological condition, the first reaction gas and the second reaction gas forming a low dielectric constant material layer on the target structure; and
adjusting the first technological condition to a second technological condition, the first reaction gas and the second reaction gas forming a protective layer on the low dielectric constant material layer.

10. The method for manufacturing a semiconductor structure according to claim 9, wherein the first reaction gas comprises at least one type of cyclic organosiloxane, and the second reaction gas comprises at least one type of oxygen-containing gas.

11. The method for manufacturing a semiconductor structure according to claim 10, wherein the at least one type of cyclic organosiloxane comprises octamethylcyclotetrasiloxane, and the at least one type of oxygen-containing gas comprises oxygen.

12. The method for manufacturing a semiconductor structure according to claim 9, wherein a flow ratio of the first reaction gas to the second reaction gas introduced into the reaction chamber is adjusted while the first technological condition is adjusted to the second technological condition.

13. The method for manufacturing a semiconductor structure according to claim 9, wherein the adjusting a technological condition in the reaction chamber to a first technological condition, the first reaction gas and the second reaction gas forming a low dielectric constant material layer on the target structure comprises:
introducing the first reaction gas into the reaction chamber at a first flow rate, and introducing the second reaction gas into the reaction chamber at a second flow rate; and
turning on a radio frequency source, so that the radio frequency source outputs a first radio frequency power, introducing an inert gas, controlling a flow rate of the inert gas to be a fifth flow rate, and adjusting a pressure in the reaction chamber to a first pressure, wherein the first reaction gas and the second reaction gas undergo a first chemical reaction, and a reaction product of the first chemical reaction is deposited on the target structure to form the low dielectric constant material layer.

14. The method for manufacturing a semiconductor structure according to claim 13, wherein the first radio frequency power comprises a low frequency ranging from 45 W to 55 W and a high frequency ranging from 540 W to 660 W; the fifth flow rate ranges from 2200 sccm to 2800 sccm; and the first pressure ranges from 4 Torr to 6 Torr.

15. The method for manufacturing a semiconductor structure claim 13, wherein the first flow rate ranges from 2500 sccm to 3500 sccm; and the second flow rate ranges from 120 sccm to 180 sccm.

16. The method for manufacturing a semiconductor structure according to claim 13, wherein the adjusting the first technological condition to a second technological condition, and forming a protective layer by deposition on the low dielectric constant material layer comprises:
adjusting an output power of the radio frequency source to a second radio frequency power, adjusting the flow rate of the inert gas to a sixth flow rate, and adjusting the pressure in the reaction chamber to a second pressure; and adjusting the first reaction gas from the first flow rate to a third flow rate, and adjusting the second reaction gas from the second flow rate to a fourth flow rate, wherein
the first reaction gas and the second reaction gas undergo a second chemical reaction, and a reaction product of the second chemical reaction is deposited on the low dielectric constant material layer to form the protective layer.

17. The method for manufacturing a semiconductor structure according to claim 16, wherein the second radio frequency power comprises a low frequency ranging from 80 W to 100 W and a high frequency ranging from 300 W to 500 W; the sixth flow rate ranges from 1500 sccm to 2000 sccm; and the second pressure ranges from 7 Torr to 8 Torr.

18. The method for manufacturing a semiconductor structure according to claim 16, wherein the third flow rate ranges from 400 sccm to 500 sccm; and the fourth flow rate ranges from 200 sccm to 500 sccm.

19. The method for manufacturing a semiconductor structure according to claim 9, wherein the reaction chamber is maintained under the second technological condition for preset duration, the protective layer with a first thickness is formed on the low dielectric constant material layer, and the first thickness ranges from 30 nm to 50 nm.

20. The method for manufacturing a semiconductor structure according to claim 9, wherein a dielectric constant of the low dielectric constant material layer is less than 3.
